(19) United States
(12) Patent Application Publication
(10) Pub. No.: US 2002/0081802 A1
(43) Pub. Date: Jun. 27, 2002

(54) Interconnect to plate contact/via arrangement for random access memory

(76) Inventors: Ritu Shrivastava, Fremont, CA (US); Chitranjan N. Reddy, Los Altos Hills, CA (US)

Correspondence Address: BEYER WEAVER & THOMAS LLP, P.O. BOX 778, BERKELEY, CA, 94704-0778, US

(21) Appl. No.: 10/005,595

(22) Filed: Nov. 7, 2001

Related U.S. Application Data
(63) Continuation of application No. 09/497,977, filed on Feb. 4, 2000, now abandoned.
Application No. 09/497,977 is a continuation of application No. 08/837,529, filed on Apr. 21, 1997, now abandoned.

(51) Int. Cl. H01L 21/8242

(52) U.S. Cl. 438/250

(57) ABSTRACT

A DRAM device (200) is disclosed having a plurality of memory cells (208) formed on a substrate (202). Each memory cell (208) includes a transistor (210) having a gate (212), and a storage capacitor (214) having a bottom plate (226) covered with a capacitor dielectric (234). A relatively thin top plate (236) is formed over a number of memory cells (208) in a array portion (204) of the DRAM device (200). The top plate (236) extends to a peripheral array portion (206) where contact is made thereto by metallization (248), by way of a plate contact hole (244). An etch stop (240), formed from the same layer as the gate (212) in the preferred embodiment, is disposed in the peripheral array portion (206) below the plate contact hole (244). The etch stop (240) provides greater flexibility in the plate contact hole etching step, by preventing the plate contact hole (244) from extending through the top plate (236) and to the substrate (202).

### RELATED APPLICATIONS

This is a Continuation application of copending prior application Ser. No. 09/497,977 filed on Feb. 4, 2000, which is a continuation of prior application Ser. No. 08/837,529 filed on Apr. 21, 1997, which hereby takes priority therefrom.

### TECHNICAL FIELD

The present invention relates generally to the formation of vertical interconnects between conductive layers in an integrated circuit, and more particularly to forming an electrical connection between a dynamic random access memory array common capacitor plate and an overlying conductive layer.

### BACKGROUND OF THE INVENTION

Many integrated circuit designs include similar circuit elements, such as logic cells and/or memory cells, that are commonly covered by a conductive layer that is maintained at a predetermined potential. For example, it is known in the prior art to construct dynamic random access memory (DRAM) arrays having stacked cell capacitors, each having a first and second capacitor plate. The first plate of each capacitor is individually patterned for each cell from a first conductive layer, while the second plate for all, or a portion of the capacitors within the array, is formed from a relatively large, overlying plate member patterned from a second conductive layer.

In many DRAM designs, the large second plate (referred herein as the “common plate”) is formed from a layer of polysilicon, and held at a zero volt (ground) potential. Typically, the common plate is coupled via one or more contacts to an overlying metallization pattern that is connected to the ground reference potential. Previously, the metal-to-common plate contact could be formed with relative reliability. Currently, however, many DRAM approaches seek to increase the capacitance of the memory cell capacitors by extending the capacitor structures vertically with respect the substrate of the DRAM. As a result, the resulting aspect ratio of the metal-to-common plate contact is increased. This, in connection with the use of thinner polysilicon layers, has introduced reliability issues in the formation of metal-to-common plate contacts.

An example of the problem related to high metal-to-common plate contact aspect ratios is set forth in the side cross sectional views of FIGS. 1a-1b. FIG. 1 a sets forth a portion of a DRAM device after the formation of the memory cells, but prior to the formation of a metal-to-common plate contact. The DRAM device is formed on a semiconductor substrate 1 and includes an array portion 2 and a peripheral portion 3. A DRAM memory cell 4, one of many, is formed in the array portion 2. The memory cell 4 includes an access transistor 5 and a storage capacitor 6. The access transistor is an insulated gate field effect transistor and includes a gate 7 formed from a first layer of doped polysilicon 8 and silicide 9. The gate 7 is insulated by insulating sidewalls 10 and an insulating cap 11. Portions of an interpoly dielectric layer 12 are shown insulating the capacitor 6 from the substrate 1 and gate 7. The capacitor 6 includes a bottom plate 13 formed from a relatively thick second layer of doped polysilicon 14 and a relatively thin third layer of doped polysilicon 15. Formed over the bottom plate 13 is a capacitor dielectric 16. It is noted that the capacitor dielectric 16 extends into the peripheral portion 3 of the DRAM device. Covering the capacitor dielectric 16 is the top common capacitor plate 17 which is formed from a relatively thin fourth layer of doped polysilicon. As in the case of the capacitor dielectric 16 the common capacitor plate 17 extends into the peripheral portion 3. A planarized interlayer dielectric 18 is formed over array portion 2 and the peripheral portion 3. It is noted that the interlayer dielectric 18 must provide a minimum insulation thickness (identified by arrow 19) over the top most portion of the memory cell 6. This results in a relatively deep interlayer dielectric 18 thickness in the peripheral portion (identified by arrow 20) .

FIG. 1b illustrates the DRAM of the prior aft following the etching of the common plate contact holes. A contact etch mask 21 having mask openings 22 is formed on the interlayer dielectric 18. An anisotropic etch is then applied which forms a contact hole 23 through the interlayer dielectric 18 to (ideally) the common plate 17. A drawback to the. high aspect ratio of the contact is that despite the contact etch's high selectivity to polysilicon, because the plate member is so thin, the contact hole 23 can extend through the common plate 17 to the substrate 1. This undesirable case is shown in FIG. 1b. The resulting contact hole 23 has exposed the substrate, and as a result, any subsequent interconnect layer formed on the interlayer dielectric 18 will make contact with the substrate 1.

It is known in the prior art to form a DRAM capacitor common plate by depositing a relatively thick layer of polysilicon. Such an approach reduces the possibility that the contact etch will etch through the entire common plate thickness. It is also known in the prior art to form a capacitor common plate that includes a top layer that is a silicide. Silicide provides a greater etch barrier than polysilicon during an oxide etch. Such approaches can add to the complexity of the fabrication process, however.

### SUMMARY OF THE INVENTION

It is an object of the present invention to provide an integrated circuit having a common plate formed from a relatively thin conductive layer, that has reliable contacts to the common plate.

It is another object of the present invention to provide a DRAM having a relatively thin capacitor plate common to a number of memory cells that is reliably maintained at a predetermined reference voltage.

It is yet another object of the present invention to provide an improved peripheral contact to a DRAM array.

The present invention includes an integrated circuit having a number of cells formed by one or more conductive layers. A common plate, formed from a relatively thin conductive layer, is disposed over the cells. The common plate also extends to a region peripheral to the cells. An insulating layer is formed over the common plate. Plate contacts to the common plate are formed in the peripheral region by etching through the insulating layer to form contact holes that expose the common plate. An etch barrier is formed below the common plate, in the peripheral region, to prevent the contact holes from extending through the common plate to the substrate.

According to one aspect of the present invention, the cells are DRAM memory cells, and the conductive plate is a capacitor plate common to a number of memory cell capacitors.

According to another aspect of the present invention, the cells are DRAM memory cells, the conductive plate is a capacitor plate common to a number of memory cell capacitors, and the etch barrier is formed from the same layer used to create gates for memory cell access transistors.

According to another aspect of the present invention, the etch barrier layer includes silicide to provide greater resistance to an oxide etch.

Other objects and advantages of the present invention will become apparent in light of the following description thereof.

### BRIEF DESCRIPTION OF THE DRAWINGS

FIGS. 1a-1b are side cross section views illustrating an undesirable contact etch possible from prior art approaches.

FIG. 2 is a side cross sectional view illustrating a DRAM device according to the preferred embodiment of the present invention.

FIGS. 3a-3l is a side cross sectional view illustrating the method for forming the DRAM device of FIG. 2 according to the preferred embodiment.

FIG. 4 is a side cross sectional view illustrating a DRAM device according to an alternate embodiment of the present invention.

### DETAILED DESCRIPTION OF THE EMBODIMENTS

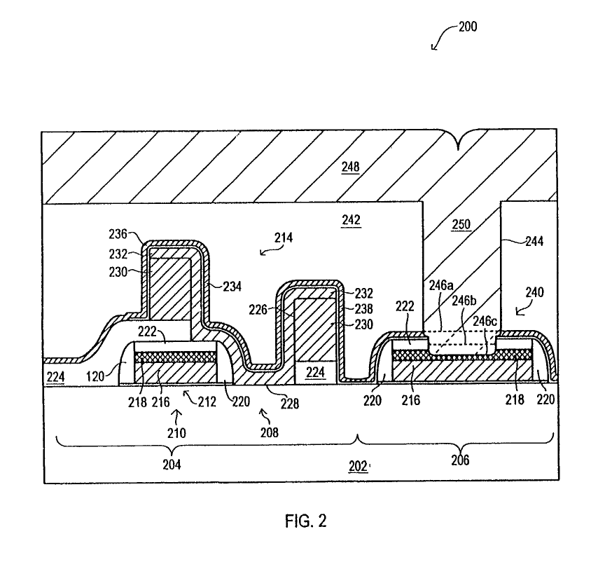

A side cross sectional view illustrating a DRAM device according to the preferred embodiment of the present invention is set forth generally in FIG. 2, and designated by the general reference character 200. The DRAM device 200 includes a semiconductor substrate 202 having an array portion 204 and a peripheral array portion 206. A number of DRAM memory cells are formed within the array portion. One such memory cell 208 is set forth in FIG. 2. The memory cell includes an insulated gate field effect transistor 210 having a gate 212 and a storage capacitor 214. The gate 212 includes a first layer of doped polysilicon (poly 1) 216 and a layer of tungsten silicide 218. The sides of the gate 212 are insulated by sidewalk spacers 220. The top of the gate 212 is insulated by a dielectric cap 222. Disposed over portions of the substrate 202 and the gate 212 is an interpoly dielectric layer 224. The storage capacitor 214 is shown to include a bottom plate 226 that overlaps the gate 212 and is coupled to the transistor 210 by making electrical contact with a capacitor contact region 228 of the substrate 202. In the preferred embodiment, the bottom plate 226 includes a second layer of relatively thick doped polysilicon (poly 2) 230 disposed above and generally surrounding the capacitor contact region 228, as well as a third layer of doped polysilicon (poly 3) 232 disposed over the poly 2 230 and extending-along the inner sides thereof to make contact with the capacitor contact region 228. The bottom plate 226 is covered by a capacitor dielectric 234, which, in the particular embodiment of FIG. 2, extends into the peripheral array portion 206 of the DRAM device 200. A common top plate 236 is disposed over the capacitor dielectric 234. The top plate 236 is comprised of a fourth layer of relatively thin doped polysilicon (poly 4) 238, and like the capacitor dielectric 234, extends into the peripheral array portion 206. It is understood that in the preferred embodiment the top plate 236 forms a common top plate 236 to a number of other DRAM memory cell capacitors not set forth in FIG.2.

Referring once again to FIG. 2, the peripheral array portion 206 of the DRAM device 200 is shown to include an etch stop 240 formed over the substrate 202. The etch stop 240 of the preferred embodiment is formed from the same conductive layers as the gate 212. Accordingly, the etch stop 240 set forth in FIG. 2, like the gate 212, includes a poly 1 layer 216, a silicide layer 218, sidewall spacers 220 and a dielectric cap 222. Both the capacitor dielectric 234 and the top plate 238 are disposed over the etch stop 240.

As set forth in FIG. 2, an interlayer dielectric 242 is disposed over the top plate 238 in both the array portion 202 and the peripheral array portion 206.

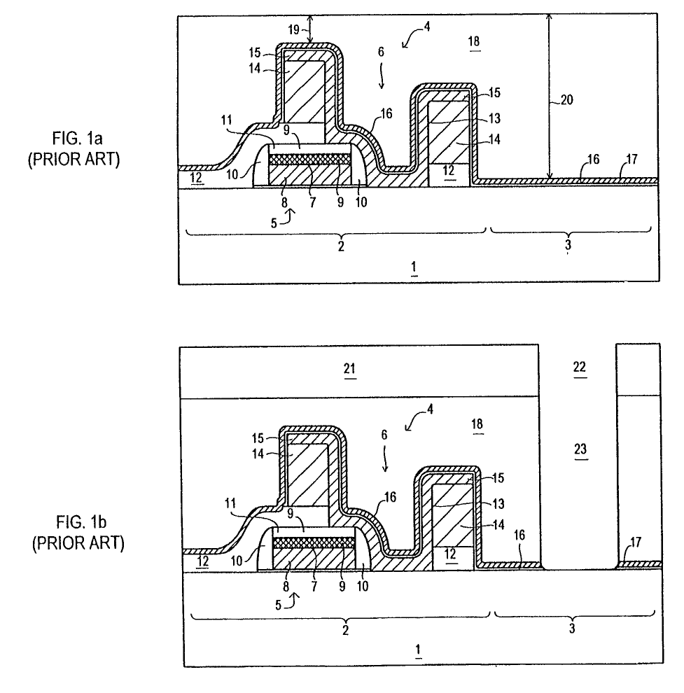

According to the present invention, a plate contact hole 244 extends through the interlayer dielectric 242 and is aligned over the etch stop 240. The plate contact hole 244 includes a plate contact hole bottom 246. In FIG. 2a three plate contact hole bottoms 246a-246c are set forth to generally illustrate possible plate contact hole variations of the present invention. Plate contact hole bottom 246a represents the ideal etch situation in which the plate contact hole bottom 246a lines up with the top plate 236. That is, the plate contact hole etch stops once the top plate 236 is sufficiently exposed. It is noted that this ideal situation is difficult to attain because the high aspect ratio of the plate contact hole 244 makes such an exacting etch difficult to reproduce. Plate contact hole bottom 246b sets forth the case where the plate contact hole 244 extends through the top plate 236 and the capacitor dielectric 234, and terminates within the dielectric cap 222 disposed over the etch stop 240. Plate contact hole bottom 246c sets forth a case in which the plate contact hole 244 extends through the top plate 236, the capacitor dielectric 234, and the dielectric cap 222, to terminate within the silicide 218 or the etch stop 240. Due to the high selectivity of the plate contact hole etch to silicide, the silicide 218 of the etch stop 240 provides etch stop layer that is more effective than the polysilicon or the dielectric layers. It is noted that the overetch cases (those represented by plate contact hole bottoms 246b and 246c) would have resulted in an exposure of the substrate in the prior art case of FIGS. 1a and 1b. Accordingly, the preferred embodiment can accommodate considerable variance in etch rate, and still protect the substrate from being exposed.

Referring again to FIG. 2, a metallization layer 248 is shown disposed over the interlayer dielectric 242. The metallization layer 248 includes a contact 250 that extends into the plate contact hole 244 and makes electrical contact with the top plate 236. While the metallization-to-top plate contact has limited surface area, numerous such contacts can be provided to increase the surface area. Further, in the case of the DRAM device 200 of the preferred embodiment, the current requirements of the top plate 236 are relatively small, as it is the common plate for a number of capacitors.

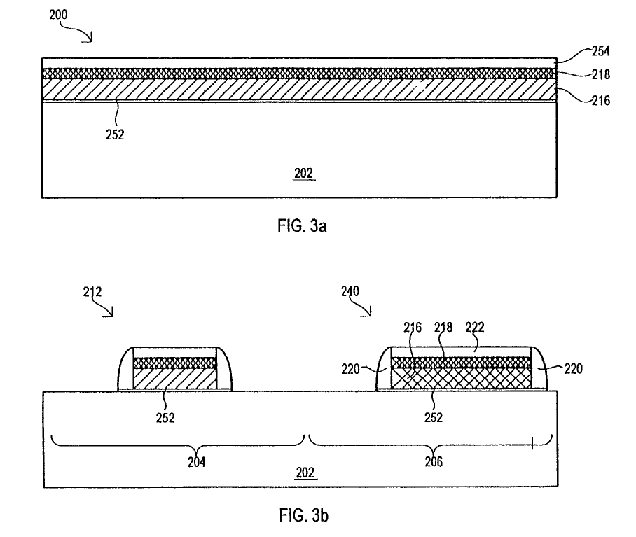

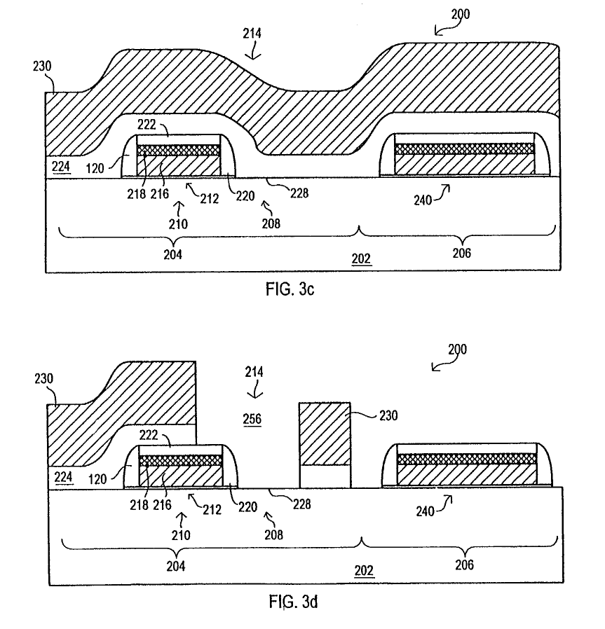

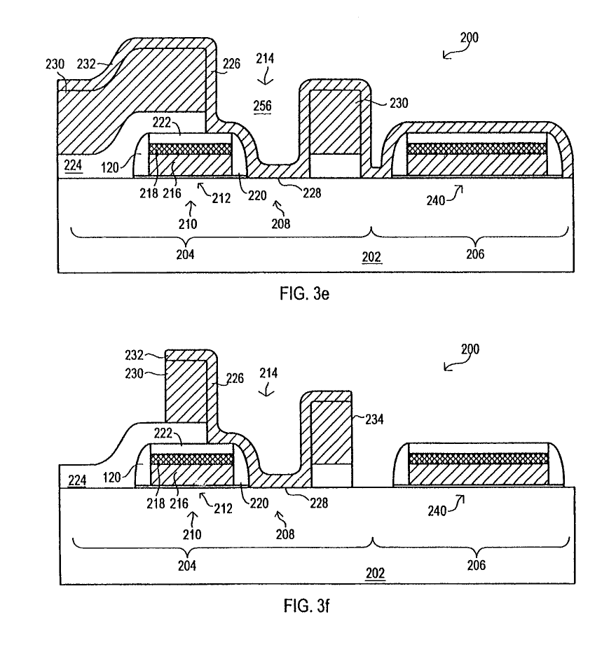

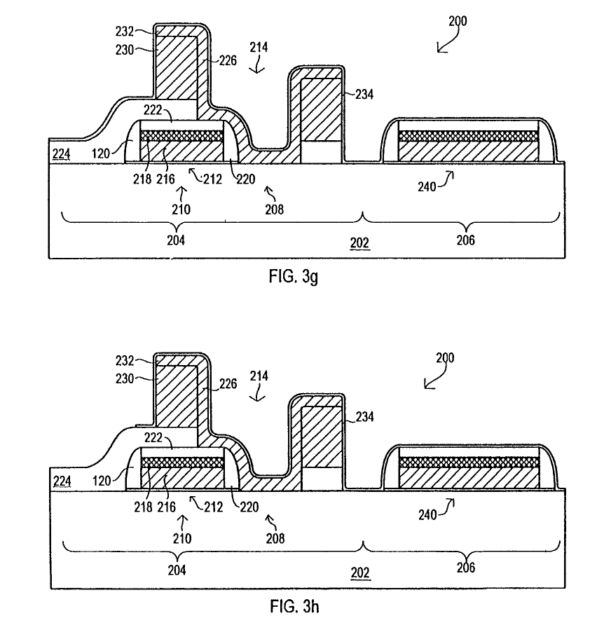

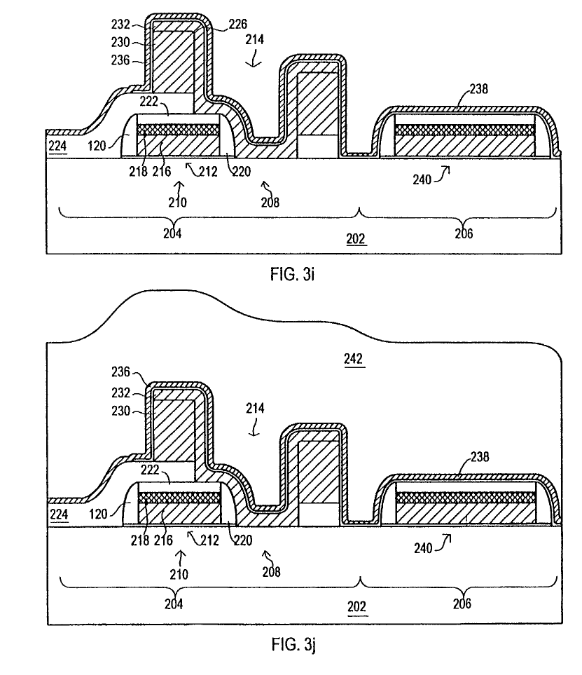

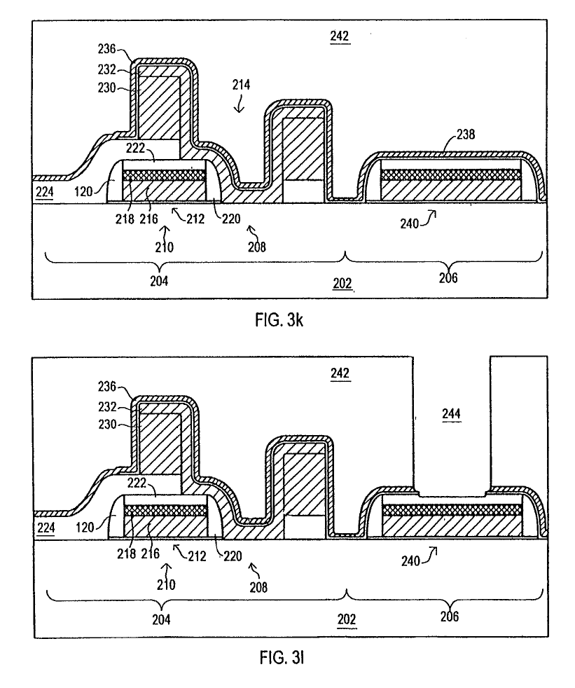

Referring now to FIGS. 3a-3j, a series of side cross sectional views corresponding to the view set forth in FIG. 2 are set forth, illustrating the fabrication of the DRAM device according to a preferred embodiment of the present invention.

Referring now to FIG. 3a, the fabrication of a DRAM device 200 according to a preferred embodiment begins with conventional metal-oxide-semiconductor processing steps. Active areas, separated by isolation regions are formed in the semiconductor substrate 202. The active areas are cleaned and a gate oxide 252 is grown. The poly 1 216 is then deposited on the surface of the DRAM device 200. The layer of silicide 218 is then deposited over the poly 1 216. Following the formation of the composite poly/silicide first conductive layer, a dielectric cap layer 254 is formed over the silicide 218. In the preferred embodiment, the gate oxide is thermally grown silicon dioxide, and has a thickness of approximately 120 A. The poly 1 layer is polycrystalline silicon deposited by chemical vapor deposition (CVD) for a thickness of approximately 1,500 A. The poly 1 layer is doped with phosphorous using conventional in situ doping techniques. Alternately, the poly 1 is doped by ion implanting phosphorous (P+31) at a concentration of 5×10¹⁵ ions/cm² and an energy of 30 KeV. The silicide 218 is tungsten silicide, deposited by CVD and has a thickness of approximately 2,000 A. The cap layer is silicon dioxide, formed by CVD, and has a thickness of approximately 2,000 A.

Referring now to FIG. 3b, the method of fabricating a DRAM device 200 according to the present invention continues with the patterning of the poly 1 216, silicide 218, and dielectric cap layer 254. Unlike prior art approaches, which would pattern only a series of gates in an array portion, the present invention produces an etch stop 240 in the peripheral array portion 206 of the DRAM device 200 in addition to a gate 212 in the array portion 204. The gate 212 and etch stop 240 are formed by creating an etch mask over the dielectric cap layer 254, and applying an anisotropic etch. This etch patterns the poly 1 216 and silicide 218 to create the gate 212, etch stop 240, and their associated dielectric caps 222. A sidewall dielectric layer is then deposited over the gate 212 and etch stop 240, and an anisotropic sidewall spacer etch is applied. As a result, the sidewall spacers 220 are formed on the sides of the gate 212 and etch stop 240. In the preferred embodiment, the sidewall dielectric layer is silicon dioxide deposited by CVD at a thickness of approximately 2,000 A.

Referring now to FIG. 3c, the formation of the DRAM device 200 continues with the deposition of the interpoly dielectric 224 over the gate 212 and the etch stop 240. Following the interpoly dielectric 224, the initial steps for creating the storage capacitor begin with the deposition of the relatively thick poly 2 230. Like the interpoly dielectric 224 the poly 2 230 covers the etch stop 240 and the gate 212. In the preferred embodiment, the interpoly dielectric 224 is silicon dioxide deposited by decomposition of tetraethoxysilane (TEOS) for a thickness of approximately 1,500 A. In the preferred embodiment, the poly 2 layer is polycrystalline silicon deposited by CVD for a thickness of approximately 3,000 A. The poly 2 is doped with phosphorous using conventional in situ doping techniques. Alternately, the poly 2 is doped by ion implanting phosphorous (P+31) at a concentration of 5×10¹⁵ ions/cm² and an energy of 30 KeV.

Referring now to FIG. 3d, the DRAM device 200 following a contact etch is set forth. A capacitor contact hole 256 is etched through the poly 2 230 to the substrate, exposing the capacitor contact region 228. The capacitor contact hole 256 partially extends over (is self-aligned with) the gate 212. Further, while the contact etch creates numerous contacts holes in the array portion 204 of the DRAM device 200, in the preferred embodiment, the peripheral array portion 206 is cleared of the poly 2 230.

Referring now to FIG. 3e, following the formation of the capacitor contact hole 256, and clearing of the peripheral array portion 206 of poly 2 230, the poly 3 232 is deposited. The poly 3 232 conformally covers the poly 2 230, and extends into the capacitor contact hole 256 to make contact with the capacitor contact region 228. In the preferred embodiment, the poly 2 layer is polycrystalline silicon deposited by chemical vapor deposition (CVD) for a thickness of approximately 2,000 A. The poly 3 is doped with phosphorous using conventional in situ doping techniques. Alternately, the poly 3 is doped by ion implanting phosphorous (P+31) at a concentration of 5×10¹⁵ ions/cm² and an energy of 30 KeV.

Referring now to FIG. 3f, the DRAM device 200 is set forth following the formation of the bottom capacitor plate 226 (or “storage node”). An anisotropic etch is applied which etches through the poly 2 230 and poly 3 232 to create the bottom plate 226.

Referring now to FIG. 3g, the capacitor dielectric 234 is formed over the DRAM device 200 conformally covering the bottom plate 226 and the etch stop 240. In the preferred embodiment, the capacitor dielectric is a composite structure having a first layer of silicon nitride deposited by CVD for a thickness of approximately 60 A. The silicon nitride is then subject to a wet oxidization to form a second layer of silicon dioxide having a thickness of approximately 25 A.

Referring now to FIG. 3h, the DRAM device 200 is set forth following the etching of the capacitor dielectric 234. The capacitor dielectric 234 is etched within the array portion 204 to insulate the various bottom plates of the DRAM device memory cells. In the preferred embodiment, the capacitor dielectric 234 also extends into the peripheral array portion 206.

Referring now to FIG. 3i, the DRAM device 200 is covered by poly 4 238 to provide a top plate 236 to the bottom plate 226 (and to a number of other bottom plates for memory cells in the array portion that are not shown in the figures). The top plate 236 extends into the peripheral array portion, over the etch stop 240. In the preferred embodiment, the poly 4 layer is polycrystalline silicon deposited by CVD for a thickness of approximately 1,000 A. The poly 4 layer is doped with phosphorous using conventional in situ techniques.

Referring now to FIG. 3j, the DRAM device 200 is covered by the interlayer dielectric (ILD) 242 in both the array portion 204 and the peripheral array portion 206. In the preferred embodiment the ILD 242 is a combination of silicon dioxide (approximately 2,000 A) and a borophosphosilicate glass (BPSG) (approximately 6,000 A).

FIG. 3k illustrates the ILD 242 after a dielectric planarization step. In the preferred embodiment planarization is accomplished by chemical-mechanical polishing. It is noted that the extent to which the storage capacitor 214 extends in the vertical direction, away from the substrate, results in a relatively large ILD 242 thickness over the etch stop 240.

Referring now to FIG. 3l, the DRAM device 200 is shown after a plate contact hole etch. A plate contact etch mask (not shown) is formed over the ILD 242, and an anisotropic etch applied, clearing a portion of the ILD 242 to create the plate contact hole 244. As noted in the detailed description associated with FIG. 2, the existence of the etch stop 240 below the plate contact hole 244 allows for greater variation in etch time. Following the plate contact hole etch, the metallization 248 is deposited and patterned, resulting in the structure set forth in FIG. 2. In the preferred embodiment the metallization 248 includes a titanium/titanium barrier having a thickness of approximately 300 A/1000 A, formed by sputtering, a tungsten plug formed by CVD deposition, having a thickness of approximately 6,000 A, formed within the plate contact hole 244, and a layer of aluminum, having a thickness of approximately 8,000 A, formed by sputtering.

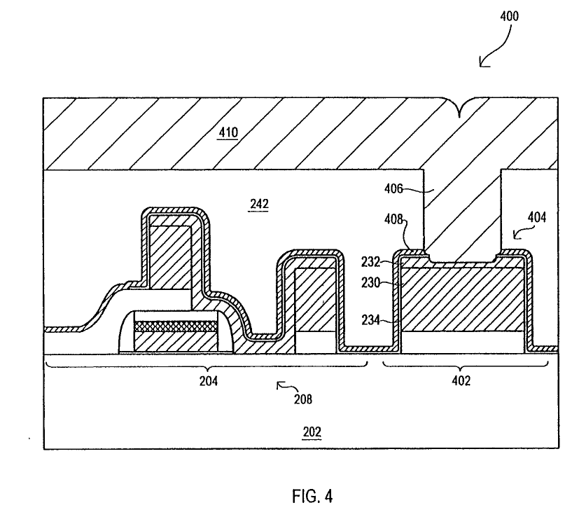

FIG. 4 sets forth an alternate embodiment of the present invention. The embodiment of FIG. 4 contains many of the same elements of the embodiment set forth in FIG. 2, and so like elements in FIG. 4 will be referred to by the same reference numerals used for FIG. 2. The alternate embodiment is a DRAM device 400 formed on a semiconductor substrate 202. The DRAM device 400 includes an array portion 204 and a peripheral array portion 402. The array portion 204 includes a memory cell 208 having the same general elements of that set forth in FIG. 2. Unlike the embodiment of FIG. 2, in the alternate embodiment, an etch stop 404 is formed from the poly 2 230 and poly 3 232 layers, as opposed to the poly 1 216 and silicide layers 218. While the etch stop 404 of the alternate embodiment lacks selectivity provided by the silicide 218 of the preferred embodiment, the etch stop 404 includes the relatively thick poly 2 230 layer, and so also provides protection against overetch. A plate contact hole 406 extends through an ILD layer 242, through the top plate 408 and into the etch stop 404. It is understood that the plate contact hole 406 could stop just at the top plate 408, within the capacitor dielectric 234, or further with the etch stop 404, providing greater variation in the plate contact hole etching step. A metallization layer 410 is formed over the ILD 242 and includes a contact 412 that extends into the plate contact hole 406 to make electrical contact with the top plate 408. It is noted that the plate contact hole 406 of the alternate embodiment has a small aspect ratio than that of FIG. 1.

It is understood that the embodiments set forth herein are only some of the possible embodiments of the present invention. Accordingly, the invention may be changed, and other embodiments derived, without departing from the spirit and scope of the invention. The invention is intended to be limited only by the appended claims.

What is claimed is:

1. A method of substantially simultaneously forming a substrate protection structure and a field effect transistor gate structure on a substrate wherein the substrate protection structure is used for protecting the substrate during a subsequent contact etch process and wherein the gate structure is included in a gate field effect transistor, comprising:
forming an etchable layer by,
depositing a gate oxide layer on the substrate;
forming a first conductive layer on the gate oxide layer;
depositing an dielectric cap layer over the first conductive layer;
applying an etch mask on the dielectric cap layer, wherein the etch mask includes a filed effect transistor gate structure etch pattern that protects a first portion of the etchable layer suitable for forming the field effect transistor gate structure and wherein the etch mask further includes a substrate protection structure etch pattern that protects a second portion of the etchable layer suitable for forming the substrate protection structure; and
substantially simultaneously forming the substrate protection structure and the field effect transistor gate structure by anisotropically etching, in a single etch process, those portions of the etchable layer that are not protected by either the field effect transistor gate structure etch pattern or the substrate protection structure etch pattern such that the substrate protection structure and the field effect transistor gate structure are formed of the same layers.

2. A method as recited in claim 1, wherein the gate oxide layer is a thermally grown layer of silicon dioxide.

3. A method as recited in claim 2, wherein the gate oxide layer is approximately 120 angstroms thick.

4. A method as recited in claim 3, wherein forming the first conductive layer comprises:
depositing a first polysilicon layer on the gate oxide layer; and
depositing a silicide layer on the first polysilicon layer.

5. A method as recited in claim 4, wherein the first polysilicon layer is formed by a chemical vapor deposition process.

6. A method as recited in claim 5, wherein the first polysilicon layer is approximately 1500 angstroms thick.

7. A method as recited in claim 6, wherein the silicide layer is formed of tungsten silicide.

8. A method as recited in claim 7, wherein the tungsten silicide layer is approximately 2000 angstroms thick.

9. A method as recited in claim 8, wherein the dielectric cap layer is formed of silicon dioxide.
